(19) United States
(12) Patent Application Publication
(10) Pub. No.: US 2010/0102741 A1
(43) Pub. Date: Apr. 29, 2010

(54) HIGH-VOLTAGE PULSE GENERATOR AND HIGH-PRESSURE DISCHARGE LAMP COMPRISING SUCH A GENERATOR

(75) Inventors: Andreas Kloss, Neubiberg (DE); Ute Liepold, Muenchen (DE); Steffen Walter, Oberpframmern (DE)

Correspondence Address: Viering, Jentschura & Partner - OSR, 3770 Highland Ave., Suite 203, Manhattan Beach, CA, 90266, US

(73) Assignee: OSRAM GESELLSCHAFT MIT BESCHRAENKTER HAFTUNG, Muenchen (DE)

(21) Appl. No.: 12/529,747

(22) PCT Filed: Feb. 15, 2008
(86) PCT No.: PCT/EP2008/051866

§ 371 Date: Sep. 3, 2009

(30) Foreign Application Priority Data
Mar. 6, 2007 (DE) 10 2007 010 899.2

(51) Int. Cl. H05B 41/30; H03K 3/00

(52) U.S. Cl. 315/246; 307/106

(57) ABSTRACT

A compact high-voltage pulse generator based on a spiral pulse generator is provided, wherein the spiral pulse generator is in the form of an LTTC component part or HTCC component part including two ceramic films of a given width and a metallic conductor applied to each of said ceramic films, which conductors are wound together in spiral form, such that the edge of the films together forms an end face in the manner of a circular ring, the two conductors being electrically insulated from one another by at least one insulation means.

### TECHNICAL FIELD

The invention is based on a high-voltage pulse generator in accordance with the precharacterizing clause of claim 1. Such generators can be used in particular for high-pressure discharge lamps for general lighting and for photo-optical purposes or for motor vehicles. The invention furthermore relates to a high-pressure discharge lamp which is equipped with such a generator.

### PRIOR ART

The problem with starting of high-pressure discharge lamps is at present solved by the starting device being integrated in the ballast. One disadvantage with this is the fact that the feed lines need to be designed so as to be able to withstand high voltages.

In the past, repeated attempts have been made to integrate the starting unit in the lamp. These attempts have included attempts to integrate the starting unit in the base. Particularly effective starting which promises high pulses has been successful by means of so-called spiral pulse generators; see U.S. Pat. No. 3,289,015. A relatively long time ago, such devices were proposed for various high-pressure discharge lamps such as metal-halide lamps or sodium high-pressure lamps; see U.S. Pat. No. 4,325,004, U.S. Pat. No. 4,353,012, for example. However, they could not gain acceptance since, firstly, they are too expensive. Secondly, the advantage of incorporating them in the base is insufficient since the problem of supplying the high voltage into the bulb remains. For this reason, the probability of damage to the lamp, whether it be insulation problems or a breakdown in the base, increases severely. Starting devices which have been conventional to date generally could not be heated to above 100° C. The voltage produced would then have to be supplied to the lamp, which requires lines and lampholders with a corresponding high-voltage strength, typically approximately 5 kV.

### DESCRIPTION OF THE INVENTION

The object of the present invention is to specify a compact high-voltage pulse generator.

This object is achieved by the characterizing features of claim 1.

Particularly advantageous configurations are given in the dependent claims.

Furthermore, an object of the present invention is to provide a high-pressure discharge lamp with a considerably improved starting response in comparison with previous lamps and with which there is no danger of any damage as a result of the high voltage. This applies in particular to metal-halide lamps, where the material of the discharge vessel can be either quartz glass or ceramic. This object is achieved by the characterizing features of claim 14.

According to the invention, a high-voltage pulse with at least 1.5 kV, which is necessary for starting the lamp, is now generated by means of a special temperature-resistant spiral pulse generator, which is integrated in the direct vicinity of the discharge vessel in the outer bulb. Not only cold starting but also hot restarting is therefore possible.

The spiral pulse generator now used is in particular a so-called LTCC component part or HTCC component part. This means that it is produced from LTCC (Low Temperature Co-fired Ceramics) or from HTCC (High instead of Low) ceramic. This material describes a special ceramic which can be made to withstand temperatures of up to 600° C. Although LTCC has already been used in connection with lamps (see US 2003/0001519 and U.S. Pat. No. 6,853,151), it was used for entirely different purposes in lamps with virtually hardly any temperature loading, with typical temperatures of below 100° C. The particular value of the high temperature stability of LTCC in connection with the starting of high-pressure discharge lamps, such as primarily metal-halide lamps with starting problems, has not been discussed in the prior art.

This spiral pulse generator is a component part which combines properties of a capacitor with those of a waveguide for producing starting pulses with a voltage of at least 1.5 kV. In order to produce such a spiral pulse generator, two ceramic “green films” with a metallic conductive paste are printed and then wound in offset fashion to form a spiral and finally isostatically pressed to form a molding. The following co-sintering of metal paste and ceramic film takes place in air in the temperature range between 800 and 1100° C., in particular in the range of from 800 to 900° C. This processing allows a use range of the spiral pulse generator of up to typically 700° C. temperature loading. As a result, the spiral pulse generator can be accommodated in the direct vicinity of the discharge vessel in the outer bulb, but also in the base or in the indirect vicinity of the lamp.

For the production of spiral pulse generators it is also possible to use ceramic “green films” with metallic conductive paste which belong to the range of sintering temperatures of HTCC materials (High Temperature Co-fired Ceramics). Examples of these materials are: Al₂O₃, ZrO₂ etc. This class of materials is densely sintered in the high temperature range of between 1100 and 1800° C.

The sintering can also take place in nitrogen (N₂), Argon (Ar), or hydrogen (H₂) or mixtures thereof, with different gas compositions and mixing ratios.

For the production of the spiral pulse generator, ceramic green films can preferably be used which, after sintering, have a relative dielectric constant (D.C.) epsilon (ε) of from 5 to 20000. This allows for a very high capacitance of the spiral capacitor and in addition a comparatively large width and energy of the high-voltage pulse produced. Values for the D.C. which are good in practice are ε=10 to 100.

This allows for a very compact design, which makes it possible for the spiral pulse generator to be integrated directly in the outer bulb of a lamp or in the base thereof. The high pulse width in addition favors the breakdown in the plasma of the discharge vessel. The high energy facilitates the transition to independent discharge.

Preferably all paste systems which have at least one metallic component and which conduct electrical current after the sintering process are suitable as the metal plating on the film. These paste systems are preferably:

Ag, Au, Cu, Mo, Ni, Pt, mixtures of Ag and Pd in accordance with the composition AgₓPd₁₋ₓ, where x is preferably in the range of from 0.5 to 0.99.

The metal plating can also be laminated in the form of metallic films onto the ceramic substrates. The thickness of the films is preferably in the range of from 1 to 100 μm. In this case, the film can be applied prior to or during the shaping winding process.

A non-metallic suitable material system for a conductive coating is graphite.

A non-metallic/inorganic material system for a conductive coating includes electrically conductive ceramics or cermets.

For the production of spiral pulse generators, in principle preferably all ceramic material systems from which ceramic green films can be drawn via a slip are suitable. The ceramic material systems (non-metallic/inorganic) in the initial state have a D.C. of between εᵣ=5 and εᵣ=20000. However, material systems and mixtures in which at least one component represents a ceramic material system are also suitable. These are in particular the materials from table 1.

TABLE 1

| Material | D.C. εᵣ (approx.) |
|---|---|
| Ceramic substrates of the | 3 to 10000 |
| LTCC technology | |
| Conventional materials in | 10 to 20000 |
| capacitor manufacture | |
| Materials from the group of | 500 to 12000, in particular |
| barium titanates and Br—Sr | 3000 to 7000 |
| titanates | |
| Materials from the group of | 15000 to 21000 |
| barium zirconate titanates | |
| Materials from the group of | 1500 to 2500 |
| lead zirconate titanates, | |
| so-called PZT, in particular | |
| hard and soft PZT | |
| PZT with additives | 8000 to 9500 |
| Materials from the group of | 18000 to 20000 |
| lead magnesium niobates, so- | |
| called PMN | |
| Materials from the group of | 17000 to 20500 |
| lead zinc niobates, so | |
| called PZN | |
| Materials from the group of | 700 to 1200 |
| potassium sodium niobates, | |
| so-called KNN | |
| Materials from the group of | 800 to 1150 |
| bismuth-based perovskites | |
| Materials from the group of | 800 to 1200 |
| tungsten bronzes | |

The advantages of such a choice of material are:
high use temperature, with the result that the spiral pulse generator can be incorporated in the direct vicinity of the lamp, in the base thereof or even in the outer bulb thereof;
small physical shape;
feedlines which withstand high voltages are no longer required;
high energy storage capacity and resultant high starting pulse energy;
the pulse width for starting a high-pressure discharge lamp can be increased depending on the D.C.; typical resultant pulse widths are 50 to 200 ns;
the charging voltage can be increased by a factor of from 5 to 200 depending on the number of windings.

A specific spiral pulse generator is manufactured for example from ceramic LTCC material with an ε of 65. The tape length is from 50 cm to 110 cm. The metal plating is a conductive paste made from Ag. The resultant spiral pulse generator has, for example, an outer diameter of approximately 1.4 cm to 2.5 cm.

Independently of this, such a spiral pulse generator can also be used for other applications since not only is it extremely stable at high temperatures, but it is also extremely compact. It is essential for this purpose that the spiral pulse generator is in the form of an LTCC component part, including ceramic films and metallic conductive paste. In order to produce sufficient output voltage, the spiral should include at least 5 turns.

In addition, on the basis of this high-voltage pulse generator, a starting unit can be specified which furthermore includes at least one charging resistor and a switch. The switch may be a spark gap or else a diac using SiC technology.

In the case of an application for lamps, it is preferable for the high-voltage pulse generator to be accommodated in the outer bulb. This means that it is no longer necessary for a voltage feed line to be used which can withstand high voltages.

In addition, a spiral pulse generator can be dimensioned in such a way that the high-voltage pulse even makes hot restarting of the lamp possible. The dielectric containing ceramic is distinguished by an extraordinarily high dielectric constant εᵣ in the range of εᵣ>10, with it being possible for an ε of typically ε=70 to 100 to be reached depending on the material and design. This provides a very high capacitance of the spiral pulse generator and makes a comparatively large temporal width and high energy of the pulses generated possible. As a result, a very compact design of the spiral pulse generator is possible, so that integration in conventional outer bulbs of high-pressure discharge lamps is successful.

The large pulse width additionally facilitates the breakdown in the discharge volume.

Any conventional glass, i.e. in particular hard glass, vycor or quartz glass, can be used as the material of the outer bulb. The choice of fill is not subject to any particular restriction either.

Until now, two conductors have been used which have approximately the same width. In order to prevent electrical flashovers between the conductor tracks, the end faces of the ceramic spiral generators are therefore equipped with an insulating layer. This is in particular a glass or resin layer. For example, this layer is a so-called overglass layer or a synthetic resin layer.

In a preferred embodiment, electrical flashovers are avoided in a more elegant manner, to be precise without using such an additional insulating layer. For this purpose, two ceramic films with a larger width than that of the metal layers are used. The first metal layer is applied in the form of a narrow track on the first ceramic film. The second narrow metal layer is applied on the second ceramic film. During lamination, the protruding ceramic layers coincide and therefore achieve simple insulation of the two metal layers at the front ends of the spiral pulse generator.

Particularly preferred is an embodiment in which a peripheral edge of ceramic insulating material without conductive paste still remains laterally on the metal layers. At best, this peripheral edge is coated with an insulating material, instead of the conductive paste coating. The thickness of this layer should be similar in size to that of the conductive paste. In this way, a difference in thickness in the wound system is prevented. The insulating layer therefore cannot “fall in” and any weakening of the peripheral edge is prevented because the insulating layer provides compensation in terms of height of the peripheral edge.

### BRIEF DESCRIPTION OF THE DRAWINGS

The invention will be explained in more detail below with reference to a plurality of exemplary embodiments. In the figures:

FIG. 1 shows the basic design of a spiral pulse generator;

FIG. 2 shows characteristics of an LTCC spiral pulse generator;

FIG. 3 shows the basic design of a high-pressure discharge lamp with a third starting electrode with a spiral pulse generator in the outer bulb;

FIG. 4 shows the basic design of a high-pressure discharge lamp with superimposed-pulse starting, with a spiral pulse generator in the outer bulb;

FIG. 5 shows a metal-halide lamp with a spiral pulse generator in the outer bulb;

FIG. 6 shows a metal-halide lamp with a spiral pulse generator in the base;

FIG. 7 shows a spiral pulse generator with an integrated spark gap;

FIG. 8 shows a spiral pulse generator with an end-side insulating layer;

FIG. 9 shows a spiral pulse generator with a single “fallen-in” peripheral edge; and

FIG. 10 shows a spiral pulse generator with height compensation of the peripheral edge.

### PREFERRED EMBODIMENT OF THE INVENTION

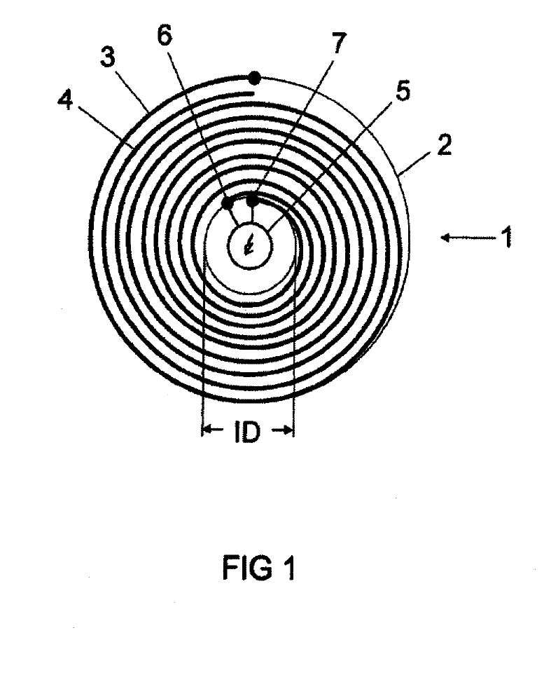

FIG. 1 shows the design of a spiral pulse generator 1 in a plan view. It includes a ceramic cylinder 2, into which two different metallic conductors 3 and 4 have been wound in the form of spirals. The cylinder 2 is hollow on the inside and has a given inner diameter ID. The two inner contacts 6 and 7 of the two conductors 3 and 4 are adjacent to one another and are connected to one another via a spark gap 5.

Only the outer of the two conductors has a further contact 8 at the outer periphery of the cylinder. The other conductor ends open. The two conductors together form a waveguide with an open end, the waveguide being realized in a dielectric medium, the ceramic.

The spiral pulse generator is either wound from two ceramic films coated with metal paste or constructed from two metal films and two ceramic green films. An important characteristic in this case is the number n of turns which should preferably be of the order of magnitude of 5 to 100. This winding arrangement is laminated and then co-sintered, as a result of which a ceramic component part, in particular an LTCC component part or else HTCC component part is produced. The spiral pulse generators thus produced with a capacitor property are then connected to a spark gap and a charging resistor.

The spark gap can be located at the inner or the outer connections or else within the winding of the generator. A spark gap can preferably be used as the high-voltage switch which initiates the pulse. Furthermore, the use of a semiconductor switch which is resistant to high temperatures, preferably using SiC technology, is possible. This is suitable for temperatures of up to 350° C.

In a specific exemplary embodiment, a ceramic material with ε=60 to 70 is used. In this case, a ceramic film, in particular a ceramic tape such as Heratape CT 700 or CT 707 or preferably CT 765, in each case from Heraeus, or else a mixture of at least two thereof, is preferably used as the dielectric. The thickness of the green film is typically from 50 to 150 μm. In particular, Ag conductive paste such as “cofirable silver”, likewise by Heraeus, is used as the conductor. A specific example is TC 7303 by Heraeus. Good results are also produced by the metal paste 6142 by DuPont. These parts can be laminated easily and then baked (“binder burnout”) and co-sintered (“co-firing”).

The inner diameter ID of the specific spiral pulse generator is 10-14 mm. The width of the individual ceramic strips is approximately 6 to 9 mm. The width of the conductor is 1 to 4 mm smaller than the width of the ceramic films. The film thickness is 50-80 μm, and the thickness of the two conductors is in each case from 7 to 12 μm. In the case of a charging voltage of 300 V, this generator generates 2500 V. With these preconditions, the spiral pulse generator reaches an optimum for its properties given a turns number of approximately n=19.

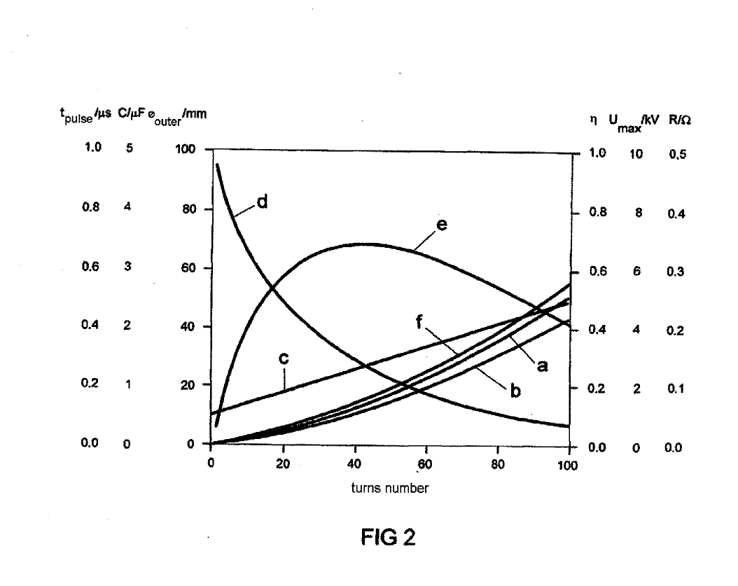

FIG. 2 illustrates the associated half-value width of the high-voltage pulse in μs (curve a), the total capacitance of the component part in μF (curve b), the resultant outer diameter in mm (curve c), and the efficiency (curve d), the maximum pulse voltage (curve e) in kV and the conductor resistance in Ω (curve f).

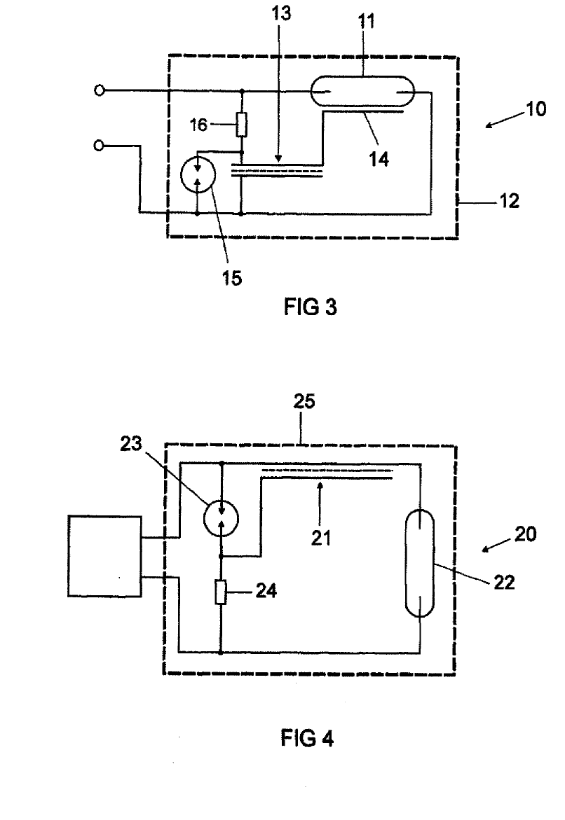

FIG. 3 shows the basic design of a high-pressure discharge lamp, in particular a sodium high-pressure discharge lamp 10, with a ceramic discharge vessel 11 and an outer bulb 12 with a spiral pulse generator 13 integrated therein, with a starting electrode 14 being fitted externally on the ceramic discharge vessel 11. The spiral pulse generator 13 is accommodated with the spark gap 15 and the charging resistor 16 in the outer bulb.

FIG. 4 shows the basic design of a high-pressure discharge lamp, in particular a metal halide lamp 20, with an integrated spiral pulse generator 21, with no starting electrode being fitted externally on the discharge vessel 22, which can be manufactured from quartz glass or ceramic. The spiral pulse generator 21 is accommodated with the spark gap 23 and the charging resistor 24 in the outer bulb 25. The high-voltage pulse is superimposed on the operating voltage of the lamp and supplied via a main electrode.

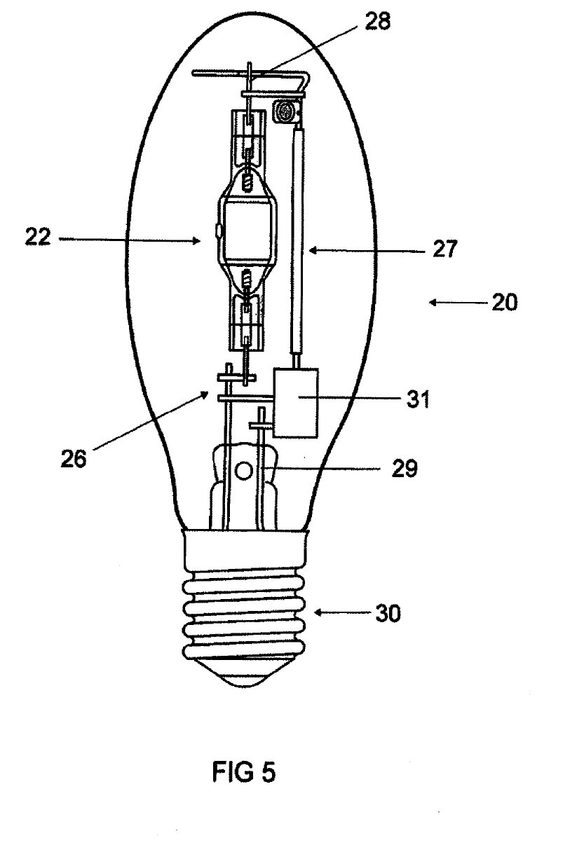

FIG. 5 shows a metal-halide lamp 20 with a discharge vessel 22, which is held by two feed lines 26, 27 in an outer bulb. The first feed line 26 is a wire with a short-angled bend. The second feed line 27 is substantially a bar, which leads to the lead through 28 remote from the base. A starting unit 31, which contains the spiral pulse generator, the spark gap and the charging resistor, is arranged between the feed line 29 emerging from the base 30 and the bar 27, as indicated in FIG. 4.

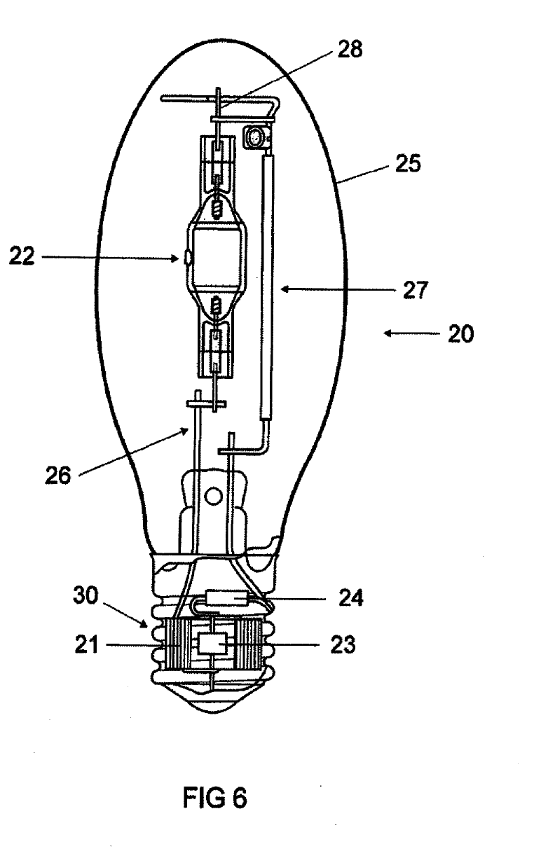

FIG. 6 shows a metal-halide lamp 20 similar to that in FIG. 5 with a discharge vessel 22, which is held by two feed lines 26, 27 in an outer bulb 25. The first feed line is a wire with a short-angled bend. The second feed line 27 is substantially a bar, which leads to the lead through 28 remote from the base. In this case, the starting unit is arranged in the base 30, to be precise both the spiral pulse generator 21 and the spark gap 23 and the charging resistor 24.

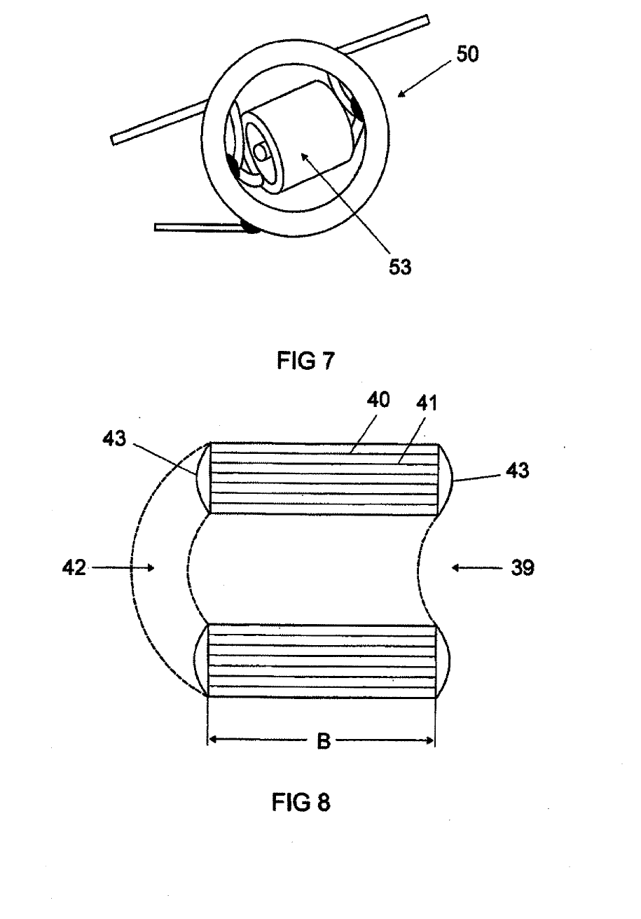

FIG. 7 shows the embodiment of a spiral pulse generator 50 with an integrated spark gap 53. It has two electrical connections in the interior at the spark gap 53 and one connection on the outer circumference.

FIG. 8 shows a ceramic spiral pulse generator 39 with insulation of the end faces in cross section. A few layers of the winding are indicated schematically, with two different metal conductors 40 and 41 being wound one inside the other. At the periphery of the ceramic strip with the width B, i.e. at the end side 42 which is in the form of a circular ring, in this case the metallic conductors 40 and 41 reach up directly to the periphery.

An insulating layer 43 is applied thereto in the form of a dome (when viewed in cross section) and insulates the two metal conductors with respect to one another and prevents a surface discharge via the ceramic layer.

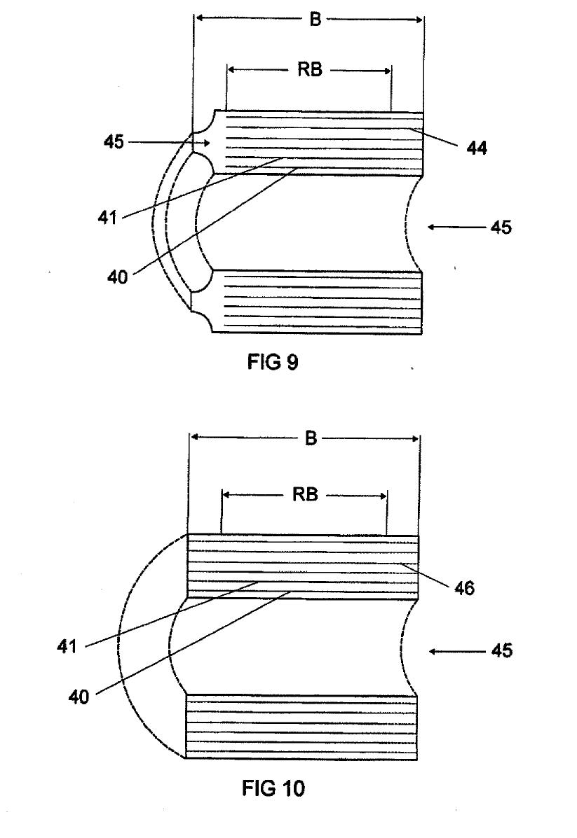

A further exemplary embodiment is shown in FIG. 9. In said figure, the spiral pulse generator 45 has two metal conductors 40, 41, whose layer does not utilize the full width B of the ceramic strip, but ends noticeably within this width (right half). The reduced with RB is advantageously RB=B−X, where X=1 to 4 mm. This improves the insulation in a very simple manner without the need for an insulating layer, but in the case of a relatively small RB results in cavities 44 in the peripheral region which may fall in. On the left-hand side, such a fallen-in peripheral region 45 is shown. This operation limits the life and stability of the spiral pulse generator. This design can therefore only be used in the case of very thin insulating layers.

FIG. 10 shows an improved version of a spiral pulse generator 45 in which, as was previously the case in FIG. 9, two metal conductors 40, 41 do not utilize the entire width B of the ceramic strip. However, in this case the peripheral cavity with the width X=B−RB is filled completely or partially, preferably to at least 80%, instead of with the metal conductor with an insulating material 46 which has approximately the same thickness as that of the metal conductors 40, 41. A suitable material is the material of the ceramic strip or an equivalent material. This results in virtually no cavity and therefore also prevents the peripheral region from falling in.

The various insulating means can also be combined with one another, with the result that, for example, an end-side insulating face interacts with a reduced width of the metal layer. It is also possible for only one of the two metal layers to have a reduced width RB in comparison with width B of the ceramic films, possibly combined with an end-side insulating face.

In addition, it is also possible for two ceramic films of different width to be used.

The invention demonstrates particular advantages when used with high-pressure discharge lamps for automobile headlamps which are filled with xenon under a high pressure of preferably at least 3 bar and metal halides. These lamps are particularly difficult to start since the starting voltage is more than 10 kV owing to the high xenon pressure. At present, attempts are being made to accommodate the components of the starting unit in the base. A spiral pulse generator with an integrated charging resistor can either be accommodated in the base of the motor vehicle lamp or in an outer bulb of the lamp.

The invention demonstrates very particular advantages when used with high-pressure discharge lamps which do not contain any mercury. Such lamps are particularly desirable for reasons of environmental protection. They contain a suitable metal halide fill and in particular a noble gas such as xenon under a high pressure. Owing to the lack of mercury, this starting voltage is particularly high. It is typically at least 5 kV, but it may also be more than 20 kV. At present, attempts are being made to accommodate the components of the starting unit in the base. A spiral pulse generator with an integrated charging resistor can be accommodated either in the base of the mercury-free lamp or in an outer bulb of the lamp.

1. A compact high-voltage pulse generator based on a spiral pulse generator, wherein the spiral pulse generator is in the form of an LTTC component part or HTCC component part comprising two ceramic films of a given width and a metallic conductor applied to each of said ceramic films, which conductors are wound together in spiral form, such that the edge of the films together forms an end face in the manner of a circular ring, the two conductors being electrically insulated from one another by at least one insulation means.

2. The high-voltage pulse generator as claimed in claim 1, wherein the insulation means is an insulating coating on the end face.

3. The high-voltage pulse generator as claimed in claim 1, wherein the insulation means is a reduced width of at least one metal conductor in comparison with the full width of the ceramic films.

4. The high-voltage pulse generator as claimed in claim 3, wherein the cavity formed by the reduced width is at least partially filled with an insulating coating.

5. The high-voltage pulse generator as claimed in claim 1, wherein the number of turns of the ceramic films is at least 5.

6. The high-voltage pulse generator as claimed in claim 1, wherein the ceramic film comprises at least one material from the group consisting of: titanates; niobates; bismuth-based perovskites; and tungsten bronzes.

7. The high-voltage pulse generator as claimed in claim 6, wherein the dielectric constant of the material is selected to be between 3 and 21000.

8. A starting apparatus, comprising:
a high-voltage pulse generator, the high-voltage pulse generator being based on a spiral pulse generator, wherein the spiral pulse generator is in the form of an LTTC component part or HTCC component part comprising two ceramic films of a given width and a metallic conductor applied to each of said ceramic films, which conductors are wound together in spiral form, such that the edge of the films together forms an end face in the manner of a circular ring, the two conductors being electrically insulated from one another by at least one insulation means;
at least one charging resistor; and
a switch.

9. A high-pressure discharge lamp, comprising:
a discharge vessel which is accommodated in an outer bulb and is held there by a frame; and
a starting apparatus, the starting apparatus comprising:
a high-voltage pulse generator, the high-voltage pulse generator being based on a spiral pulse generator, wherein the spiral pulse generator is in the form of an LTTC component part or HTCC component part comprising two ceramic films of a given width and a metallic conductor applied to each of said ceramic films, which conductors are wound together in spiral form, such that the edge of the films together forms an end face in the manner of a circular ring, the two conductors being electrically insulated from one another by at least one insulation means;
at least one charging resistor; and
a switch;
wherein the starting apparatus is integrated in the high-pressure discharge lamp.

10. The high-voltage discharge lamp as claimed in claim 9, wherein the spiral pulse generator has an approximately hollow-cylindrical design, with an inner diameter of at least 10 mm.

11. The high-voltage pulse generator as claimed in claim 5, wherein the number of turns of the ceramic films is at most 500.

12. The high-voltage pulse generator as claimed in claim 7, wherein the dielectric constant of the material is selected to be between 5 and 2000.
